(19) United States
(12) Patent Application Publication
(10) Pub. No.: US 2026/0136992 A1
(43) Pub. Date: May 14, 2026

(54) SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Chien-Chang Lin, New Taipei City (TW); Chih-Kai Cheng, Hsinchu County (TW); Hung-Min Chang, Hsinchu City (TW); Hsuan-Cheng Kuo, Hsinchu County (TW); Shih-Hui Wang, New Taipei City (TW)

(73) Assignee: Taiwan Semiconductor Manufacturing Company, Ltd., Hsinchu (TW)

(21) Appl. No.: 18/946,997

(22) Filed: Nov. 14, 2024

(51) Int. Cl. H01L 23/00; H01L 25/00; H01L 25/065

(52) U.S. Cl. CPC H10W 90/00; H10W 72/387; H10W 74/15; H10W 90/28; H10W 90/297; H10W 90/724; H10W 90/734; H10W 90/792

(57) ABSTRACT

A semiconductor package includes a substrate, a semiconductor device bonded over the substrate, a coefficient of thermal expansion (CTE) adjusting component bonded over the substrate and at least partially surrounding the semiconductor device, and an underfill material disposed between the substrate and the semiconductor device and encapsulating side surfaces of the semiconductor device and the CTE adjusting component, wherein a CTE of the CTE adjusting component is substantially lower than a CTE of the underfill material at a temperature being substantially equal to or higher than 200 Celsius.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 illustrate cross sectional views of intermediate stages in the manufacturing of a semiconductor package according to some embodiments of the present disclosure.

FIG. 10 illustrates a partial enlarged view of the semiconductor package according to some embodiments of the present disclosure.

FIG. 11 illustrates a perspective top view of the semiconductor package according to some embodiments of the present disclosure.

FIG. 12 to FIG. 14 illustrate perspective top views of semiconductor packages according to different embodiments of the present disclosure.

FIG. 15 to FIG. 23 illustrate cross sectional views of intermediate stages in the manufacturing of a semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package including a semiconductor device bonded to a package substrate with a coefficient of thermal expansion (CTE) adjusting component partially surrounding the semiconductor device and embedded in the underfill material, and the method of forming the same are provided in accordance with various embodiments. In one embodiment, the semiconductor package may include a System on Integrate Chip (SoIC) package. The intermediate stages of forming the packages are illustrated in accordance with some embodiments. Some variations of some embodiments are discussed. Throughout the various views and illustrative embodiments, like reference numbers are used to designate like elements.

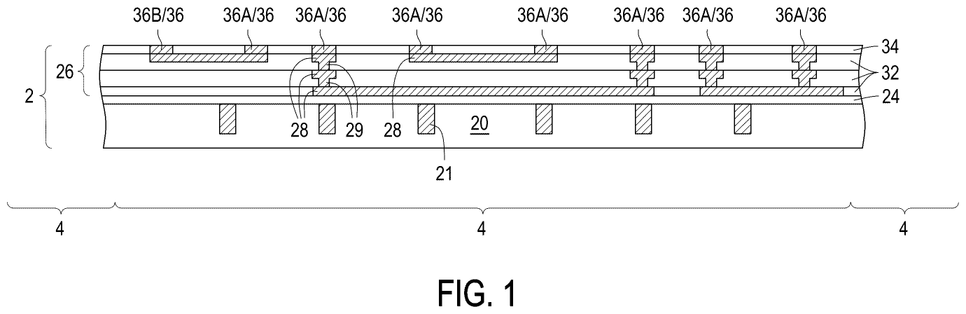

FIG. 1 to FIG. 9 illustrate cross sectional views of intermediate stages in the manufacturing of a semiconductor package according to some embodiments of the present disclosure. FIG. 1 illustrates the cross-sectional view in the formation of a wafer 2. In accordance with some embodiments of the present disclosure, the wafer 2 is an interposer wafer, which is free from any active devices such as transistors and/or diodes therein. In accordance with some embodiments of the present disclosure, the interposer wafer 2 is also free from passive devices such as capacitors, inductors, resistors, or the like therein. In some embodiments, the interposer wafer 2 may include a plurality of metal lines and vias therein, with some details of one of a plurality of interposer dies 4 illustrated schematically. The interposer dies 4 are alternatively referred to as interposers or chips hereinafter. The interposer dies 4 are used for routing, as will be discussed in subsequent paragraphs.

The wafer 2 may include a substrate 20 and the features over the top surface of the substrate 20. In accordance with some embodiments of the present disclosure, the substrate 20 is a semiconductor substrate. The substrate 20 may be formed of crystalline silicon, crystalline germanium, crystalline silicon germanium, and/or a III-V compound semiconductor such as GaAsP, AlInAs, AlGaAs, GaInAs, GaInP, GaInAsP, or the like. The semiconductor substrate 20 may also be a bulk silicon substrate or a silicon-on-insulator (SOI) substrate. In accordance with some embodiments in which the substrate 20 is a semiconductor substrate, shallow trench isolation (STI) regions (not shown) may be formed in the substrate 20 to isolate the regions in the substrate 20. In accordance with alternative embodiments, STI regions are not formed in the wafer 2 since the wafer 2 does not have active devices, and hence does not need STI regions to isolation active regions from each other. The substrate 20 may also be a dielectric substrate, which may be formed of silicon oxide, for example. In accordance with some embodiments, the wafer 2 may be a device wafer, which includes a plurality of device dies 4 therein. In accordance with some embodiments, the device dies 4 include active circuits, which include active devices such as transistors (not shown) formed at the top surface of the semiconductor substrate 20.

In accordance with some embodiments, a plurality of through vias 21 are formed to extend into the semiconductor substrate 20, wherein the through-vias are used to electrically inter-couple the features on opposite sides of the semiconductor substrate 20. The through vias 21 are also sometimes referred to as through substrate vias or through silicon vias when substrate 20 is a silicon substrate. The through vias 21 may be formed by forming recesses in the substrate 20 by, for example, etching, milling, laser techniques, a combination thereof, and/or the like. A thin dielectric material may be formed in the recesses, such as by using an oxidation technique. A thin barrier layer may be conformally deposited over the front side of the substrate 20 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 20 by, for example, CMP. Thus, the through vias 21 may include a conductive material and a thin barrier layer between the conductive material and the substrate 20. In accordance with alternative embodiments, no through-vias are formed extending into the semiconductor substrate 20.

In accordance with some embodiments, at least one dielectric layer 24 may be formed over the substrate 20. In accordance with some embodiments of the present disclosure, the dielectric layer 24 is an Inter-Layer Dielectric (ILD), which may be formed of silicon oxide, Phospho Silicate Glass (PSG), Boro Silicate Glass (BSG), Boron-Doped Phospho Silicate Glass (BPSG), Fluorine-Doped Silicate Glass (FSG), Tetra Ethyl Ortho Silicate (TEOS), or the like. The dielectric layer 24 may be formed using thermal oxidation, spin coating, Flowable Chemical Vapor Deposition (FCVD), Atomic Layer Deposition (ALD), Chemical Vapor Deposition (CVD), Plasma Enhanced Chemical Vapor Deposition (PECVD), Low Pressure Chemical Vapor Deposition (LPCVD), or the like.

Over the dielectric layer 24 resides interconnect structure 26. Interconnect structure 26 includes metal lines 28 and vias 29, which are formed in the dielectric layers 32. The dielectric layers 32 are alternatively referred to as Inter-Metal Dielectric (IMD) layers hereinafter. In accordance with some embodiments of the present disclosure, the dielectric layers 32 are formed of low-k dielectric materials having dielectric constants (k-values) lower than 3.8. For example, the k values of the dielectric layers 32 may be lower about 3.0 or lower than about 2.5. The dielectric layers 32 may be formed of Black Diamond (a registered trademark of Applied Materials), a carbon-containing low-k dielectric material, Hydrogen SilsesQuioxane (HSQ), MethylSilsesQuioxane (MSQ), or the like. In accordance with alternative embodiments of the present disclosure, some or all of the dielectric layers 32 are formed of non-low-k dielectric materials such as silicon oxide, silicon carbide (SiC), silicon carbo-nitride (SiCN), silicon oxy-carbo-nitride (SiOCN), or the like. In accordance with some embodiments of the present disclosure, the formation of the dielectric layers 32 includes depositing a porogen-containing dielectric material, and then performing a curing process to drive out the porogen, and hence the remaining dielectric layers 32 is porous. Etch stop layers (not shown), which may be formed of silicon carbide, silicon nitride, or the like, are formed between the dielectric layers 32, and are not shown for simplicity.

A plurality of metal lines 28 and vias 29 are formed in the dielectric layers 32. The metal lines 28 at a same level are collectively referred to as a metal layer hereinafter. In accordance with some embodiments of the present disclosure, interconnect structure 26 includes a plurality of metal layers that are interconnected through vias 29. The metal lines 28 and vias 29 may be formed of copper or copper alloys, and they can also be formed of other metals. The formation process may include single damascene and dual damascene processes. In a single damascene process, a trench is first formed in one of the dielectric layers 32, followed by filling the trench with a conductive material. A planarization process such as a CMP process is then performed to remove the excess portions of the conductive material higher than the top surface of the IMD layer, leaving a metal line in the trench. In a dual damascene process, both a trench and a via opening are formed in an IMD layer, with the via opening underlying and in spatial communication with the trench. The conductive material is then filled into the trench and the via opening to form a metal line and a via, respectively. The conductive material may include a diffusion barrier layer lining the trench and the via and a copper-containing metallic material over the diffusion barrier layer. The diffusion barrier layer may include titanium, titanium nitride, tantalum, tantalum nitride, or the like.

Then, a surface dielectric layer 34 is formed of a non-low-k dielectric material such as silicon oxide. The surface dielectric layer 34 is alternatively referred to as a passivation layer since it has the function of isolating the underlying low-k dielectric layers (if any) from the adverse effect of detrimental chemicals and moisture. The surface dielectric layer 34 may also have a composite structure including more than one layer, which may be formed of silicon oxide, silicon nitride, Undoped Silicate Glass (USG), or the like. Interposer dies 4 may also include metal pads underlying the surface dielectric layer 34, and the metal pads may include aluminum or aluminum copper pads, Post-Passivation Interconnect (PPI), or the like, which are not shown for simplicity.

Then, a plurality of bond pads 36A and 36B, which are also collectively and individually referred to the bond pads 36, are formed in the surface dielectric layer 34. In accordance with some embodiments of the present disclosure, the bond pads 36A and 36B are formed through a single damascene process, and may also include barrier layers and a copper-containing material formed over the barrier layers. In accordance with alternative embodiments of the present disclosure, the bond pads 36A and 36B are formed through a dual damascene process. Some of the bond pads 36A may be electrically coupled to other bond pads 36A and 36B through the metal lines 28 and vias 29. In accordance with some embodiments of the present disclosure, each of the bond pads 36A and bond pads 36B is electrically connected to at least one (or more) of other bond pads 36A and 36B through metal lines 28 and vias 29, and none of the bond pads 36A and 36B is electrically disconnected to all other bond pads 36A and 36B.

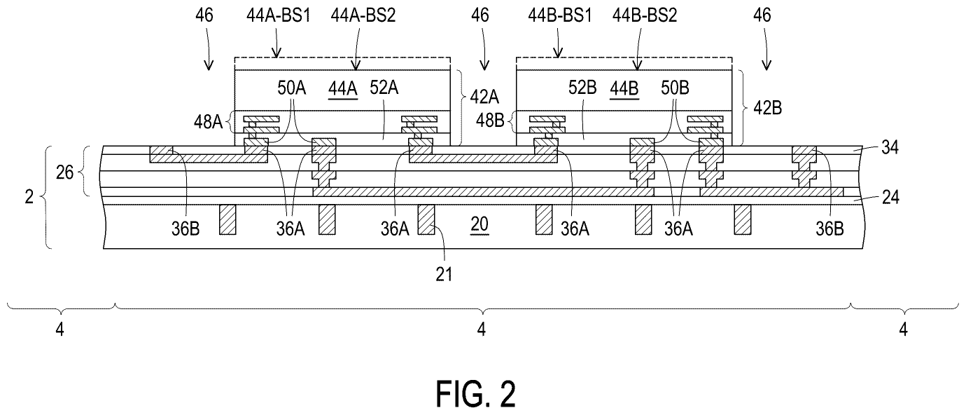

Next, referring to FIG. 2, at least one device die is bonded to the wafer 2. In the present embodiment, a plurality of device dies 42A and 42B are bonded to the wafer 2, as shown in FIG. 2, and the number of the device dies is not limited thereto. In accordance with some embodiments of the present disclosure, the device dies 42A and 42B are memory dies such as Dynamic Random Access Memory (DRAM) dies or Static Random Access Memory (SRAM) dies. One or each of the device dies 42A and 42B may also be a Central Processing Unit (CPU) die, a Micro Control Unit (MCU) die, an input-output (IO) die, a BaseBand (BB) die, or an Application processor (AP) die. The device dies 42A and 42B may be the same type or different types of dies selected from the above-listed types. The dies 4, device dies 42A and 42B in combination function as a package, which may be a memory package or logic package.

The device dies 42A and 42B include substrates 44A and 44B, respectively, which may be semiconductor substrates such as silicon substrates. In accordance with some embodiments, the substrates 44A and 44B are also referred to as semiconductor substrates 44A and 44B. In accordance with some embodiments of the present disclosure, the device dies 42A and 42B may be free from through silicon vias (TSVs) therein. Also, the device dies 42A and 42B include interconnect structures 48A and 48B, respectively, for connecting to the active devices and passive devices in the device dies 42A and 42B. The interconnect structures 48A and 48B include metal lines and vias, which are illustrated schematically. In some embodiments, the substrates 44A and 44B may be free from through-vias therein. Accordingly, all external electrical connections of the device dies 42A and 42B are made through the bond pads 50A and 50B.

In some embodiments, the device die 42A includes a plurality of bond pads 50A and dielectric layer 52A at the illustrated bottom surface. The bottom surfaces of bond pads 50A are coplanar with the bottom surface of dielectric layer 52A. Similarly, the device die 42B includes a plurality of bond pads 50B and dielectric layer 52B at the illustrated bottom surface. The bottom surfaces of the bond pads 50B are coplanar with the bottom surface of dielectric layer 52B.

The bonding of the device dies 42A and 42B to wafer 2 may be achieved through direct bonding and/or fusion bonding. For example, the bond pads 50A and 50B are bonded to the bond pads 36A through direct metal bonding (i.e., metal-to-metal direct bonding). In accordance with some embodiments of the present disclosure, the metal-to-metal direct bonding is copper-to-copper direct bonding. Furthermore, the dielectric layers 52A and 52B are bonded to the surface dielectric layer 34, for example, with fusion bonds (which may include Si—O—Si bonds) generated.

To achieve the hybrid bonding, the device dies 42A and 42B are first pre-bonded to the surface dielectric layer 34 and the bond pads 36A by lightly pressing the device dies 42A and 42B against the interposer die 4. Although two device dies 42A and 42B are illustrated, the hybrid bonding may be performed at wafer level, and a plurality of device die groups identical to the illustrated die group including device dies 42A and 42B is pre-bonded, and arranged as rows and columns.

After all device dies 42A and 42B are pre-bonded, an anneal process is performed to cause the inter-diffusion of the metals in the bond pads 36A and the corresponding overlying bond pads 50A and 50B. The annealing temperature may be in the range between about 200° and about 400° C., and may be in the range between about 300° and about 400° C. in accordance with some embodiments. The annealing time is in the range between about 1.5 hours and about 3.0 hours, and may be in the range between about 1.5 hours and about 2.5 hours in accordance with some embodiments. Through the hybrid bonding, the bond pads 50A and 50B are bonded to the corresponding bond pads 36A through direct metal bonding caused by metal inter-diffusion.

The surface dielectric layer 34 is also bonded to dielectric layers 52A and 52B, with bonds formed therebetween. For example, the atoms (such as oxygen atoms) in one of the surface dielectric layer 34 and the dielectric layers 52A/52B form chemical or covalence bonds with the atoms (such as silicon atoms) in the other one of the surface dielectric layers 34 and the dielectric layer 52A/52B. The resulting bonds between the surface dielectric layers 34 and the dielectric layer 52A/52B are dielectric-to-dielectric bonds. The bond pads 50A and 50B may have sizes greater than, equal to, or smaller than, the sizes of the respective bond pads 36A. The gaps 46 are left between neighboring device dies 42A and 42B.

Further referring to FIG. 2, a backside grinding may be performed to thin the device dies 42A and 42B, for example, to a thickness between about 15 μm and about 30 μm. FIG. 2 schematically illustrates dashed lines 44A-BS1 and 44B-BS1, which are the back surfaces of the device dies 42A and 42B, respectively before the backside grinding. Solid lines 44A-BS2 and 44B-BS2 are the back surfaces of device dies 42A and 42B, respectively after the backside grinding. Through the thinning of the device dies 42A and 42B, the aspect ratio of gaps 46 between neighboring device dies 42A and 42B is reduced. Otherwise, the gap-filling may be difficult due to the otherwise high aspect ratio of gaps 46. In accordance with other embodiments in which the aspect ratio of gaps 46 is not too high for gap filling, the backside grinding is skipped.

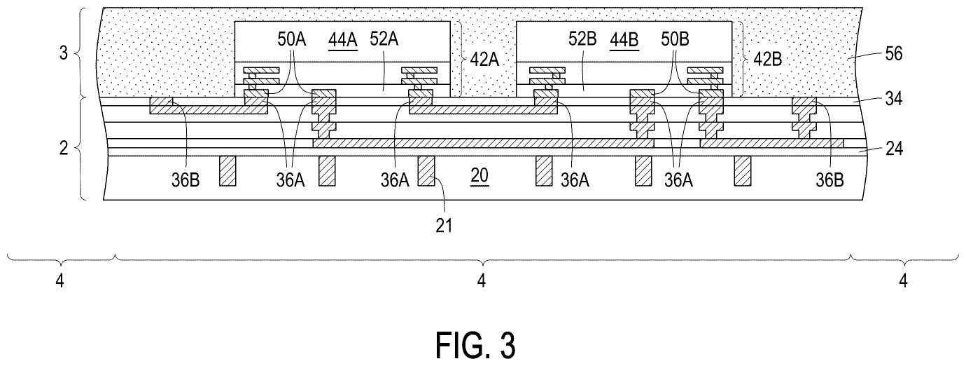

Then, referring to FIG. 3, in accordance with some embodiments of the present disclosure, an encapsulating material 56 is formed over the wafer 2. The encapsulating material 56 at least laterally encapsulates the device dies 42A and 42B. The encapsulating material 56 includes dielectric material, which may be deposited using a conformal deposition method such as Atomic Layer Deposition (ALD) or Chemical Vapor Deposition (CVD), or a non-conformal deposition method such as High-Density Plasma Chemical Vapor Deposition (HDPCVD), Flowable Chemical Vapor Deposition (CVD), spin-on coating, or the like.

In some embodiments, the encapsulating material 56 may be formed of an inorganic dielectric material. In accordance with some embodiments of the present disclosure, the encapsulating material 56 includes an oxide such as silicon oxide, which may be formed of TEOS, while other dielectric materials such as silicon carbide, silicon oxynitride, silicon oxy-carbo-nitride, or the like may also be used. The encapsulating material 56 fully fills gaps 46 (FIG. 2), and further includes some portions overlapping device dies 42A and 42B. The encapsulating material 56 may be formed of a non-conformal formation method or a conformal formation method.

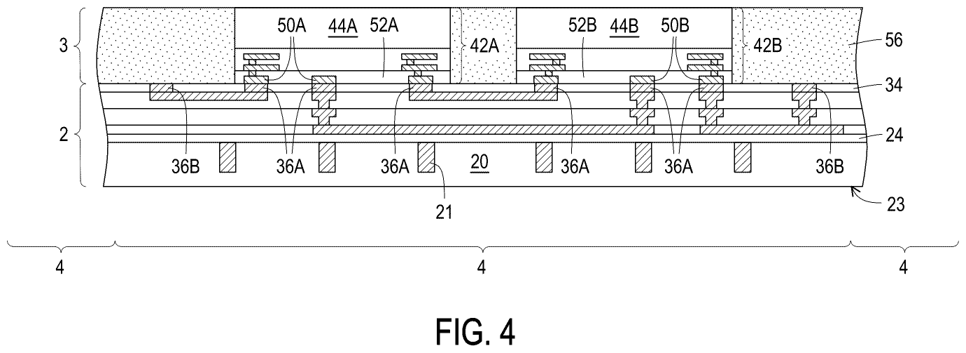

Then, referring to FIG. 4, a planarization process such as a CMP process or a mechanical grinding process is performed to remove the excess portions of the encapsulating material 56. In accordance with some embodiments of the present disclosure, the planarization is stopped when there is a layer of the encapsulating material 56 overlapping the device dies 42A and 42B. As a result, after the planarization process, the substrates 44A of the device die 42A and the substrate 44B of the device die 42B are exposed, and the exposed back surfaces of the device dies 42A and 42B are substantially coplanar with the top surface of the encapsulating material 56. At the time, a reconstructed wafer 3 over the wafer 2 is formed.

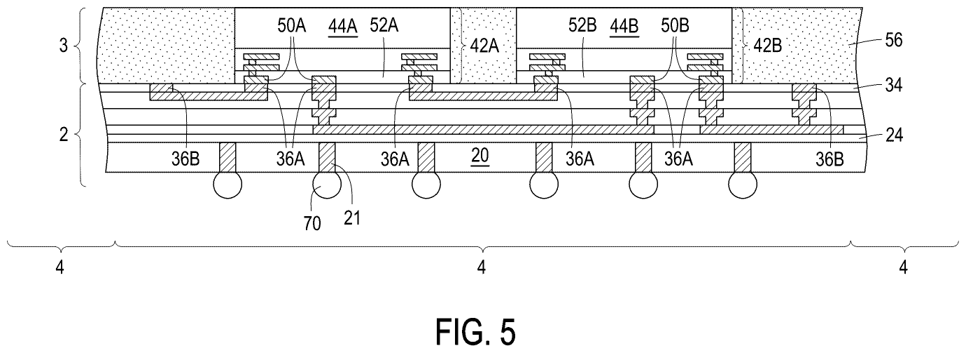

Then, referring to FIG. 5, a thinning process is performed on a back side 23 of the substrate 20 to thin the substrate 20 until the through vias 21 are exposed. In detail, the structure of FIG. 4 may be flipped over to prepare for the formation of the back side 23 of the wafer 2. Although not shown, the structure may be placed on a carrier or support structure for the process of FIG. 5. The thinning process may include an etching process, a grinding process, the like, or a combination thereof.

A redistribution structure (not shown) may be formed on the back side 23 of the substrate 20, and is used to electrically connect the through vias 21 together and/or to external devices. The redistribution structure includes one or more dielectric layers and metallization patterns in the one or more dielectric layers. The metallization patterns may comprise vias and/or traces to interconnect the through vias 21 together and/or to an external device. The metallization patterns are sometimes referred to as Redistribution Lines (RDLs). The dielectric layers may comprise silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. The metallization patterns may be formed in the dielectric layer, for example, by using photolithography techniques to deposit and pattern a photoresist material on the dielectric layer to expose portions of the dielectric layer that are to become the metallization pattern.

In FIG. 5, a plurality of conductive bumps 70 are formed over the redistribution structure and are electrically coupled to the through vias 21. In some embodiments, the metallization patterns include UBMs. In the illustrated embodiment, the pads are formed in openings of the dielectric layers of the redistribution structure. In another embodiment, the pads (UBMs) can extend through an opening of a dielectric layer of the redistribution structure and also extend across the top surface of the redistribution structure.

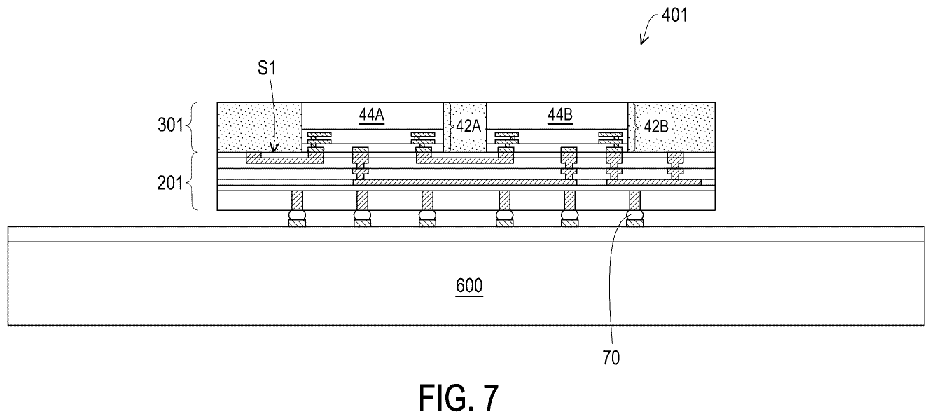

In some embodiments, the conductive bumps 70 are solder balls and/or bumps, such as ball grid array (BGA) balls, C4 micro bumps, ENIG formed bumps, ENEPIG formed bumps, or the like. The conductive bumps 70 may include a conductive material such as solder, copper, aluminum, gold, nickel, silver, palladium, tin, the like, or a combination thereof. In some embodiments, the conductive bumps 70 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive bumps 70 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive bumps 70. The metal cap layer may include nickel, tin, tin-lead, gold, silver, palladium, indium, nickel-palladium-gold, nickel-gold, the like, or a combination thereof and may be formed by a plating process. The conductive bumps 70 may be used to bond to an additional electrical component, which may be a semiconductor substrate, a package substrate, a Printed Circuit Board (PCB), or the like (see 600 in FIG. 7).

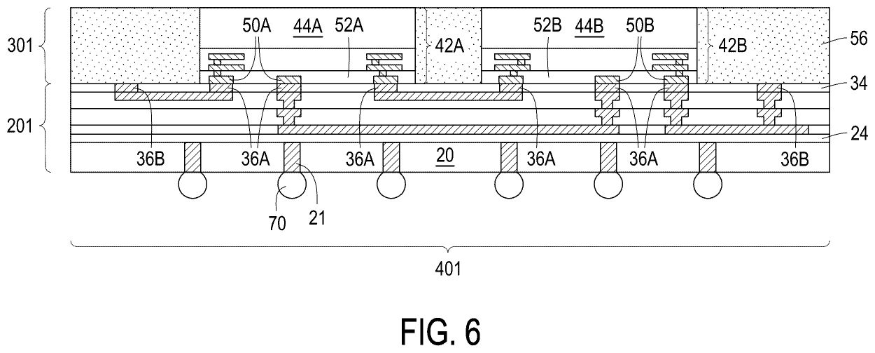

Throughout the description, the structure shown in FIG. 5 is referred to as composite wafer, which includes a reconstructed wafer 3 bonded over the wafer 2. Then, referring to FIG. 6, a singulation (die-saw) process is performed on composite wafer shown in FIG. 5 to separate the composite wafer into a plurality of semiconductor devices 401. One of the semiconductor devices 401 is illustrated in FIG. 6. In some embodiments, the semiconductor device 401 is a die stack structure, which includes a first die 201, and a second die 301 stacked over and bonded to the first die 201. The singulation process may include sawing, dicing, or the like. To be more specific, the singulation process is performed on the encapsulating material 56 and the wafer 2 to separate the composite wafer into a plurality of die stack structures 401. After the singulation process, the first die 201 is singulated from the interposer wafer 2, and the second die 301 is singulated from the reconstructed wafer 3 and bonded to the first die 201 through hybrid bonding. Accordingly, in the embodiment, the second die 301 includes a plurality of device die 42A and 42B encapsulated by the encapsulating material 56. In other embodiment, the first die 201 and the second die 301 may both be device dies and directly bonded to the each other through hybrid bonding. The disclosure is not limited thereto.

FIG. 7 illustrates the bonding of the die stack structure 401 onto a substrate 600. The conductive bumps 70 are aligned to, and are put against, the bond pads of the substrate 600. The conductive bumps 70 may be reflowed to create a bond between the substrate 600 and the die stack structures 401. The substrate 600 may comprise a package substrate, such as a build-up substrate including a core therein, a laminate substrate including a plurality of laminated dielectric films, a PCB, or the like. The substrate 600 may comprise electrical connectors (not shown), such as solder balls, opposite the component package to allow the substrate 600 to be mounted to another device. In the die stack structure 401, the first die 201 is bonded to the substrate 300 through the conductive bumps 70 and the second die 301 is stacked over and bonded to the first die 201 through hybrid bonding (e.g., fusion bonding and direct metal bonding). That is, there is no conductive bumps between the first die 201 and the second die 301, and the first die 201 and the second die 301 are in direct contact with each other.

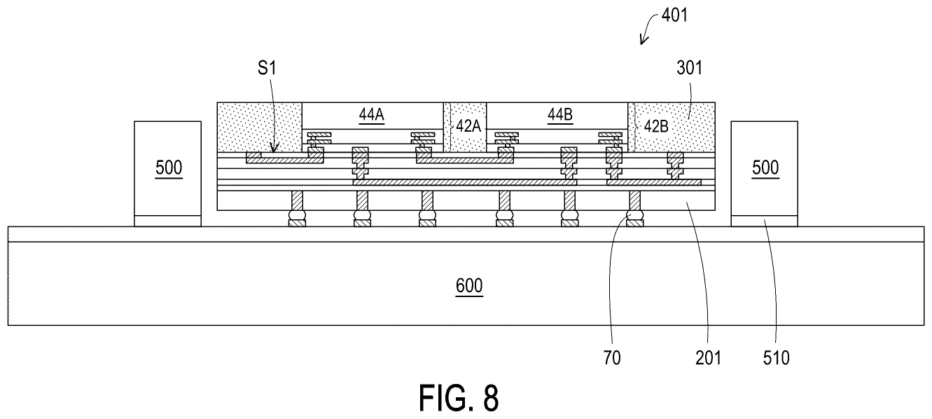

Then, referring to FIG. 8, a dam structure 500 is attached onto the substrate 600 in accordance with some embodiments. More specifically, the dam structure 500 at least partially surrounds the die stack structure 401 in accordance with some embodiments. The dam structure 500 may be attached to the substrate through an adhesive 510 such as a die attach film (DAF), or the like. In some embodiments, the dam structure 500 can be seen as a coefficient of thermal expansion (CTE) adjusting component, which is made of composite material for adjusting issues of CTE mismatch of the semiconductor package. The characteristics of the CTE adjusting component 500 would be described in more detail later on.

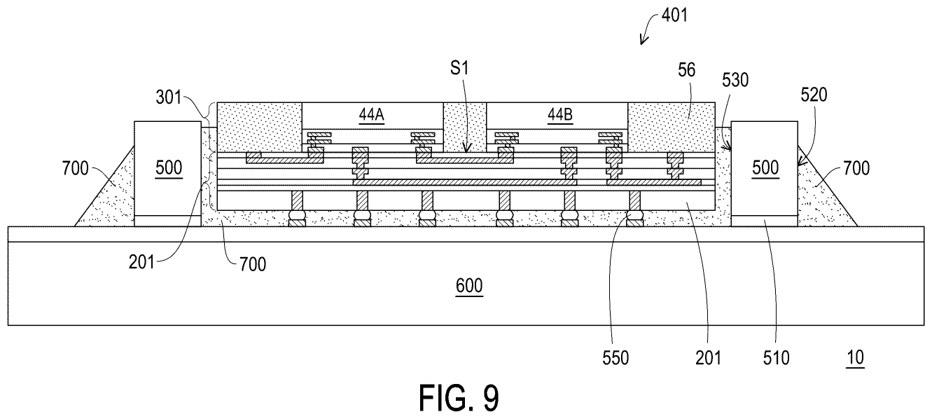

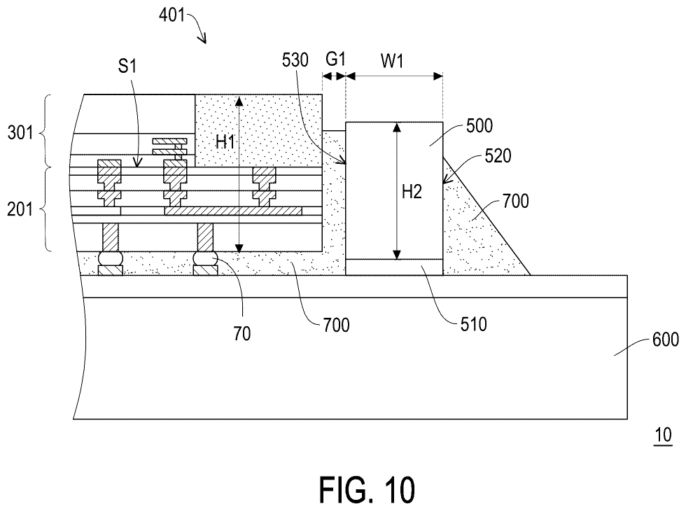

FIG. 10 illustrates a partial enlarged view of the semiconductor package according to some embodiments of the present disclosure. Referring to FIG. 9 and FIG. 10, then, an underfill material 700 is provided over the substrate 600. The underfill material 700 is filled in the space between the substrate 600 and the die stack structure 401, and the underfill material 700 encapsulates side surfaces of the die stack structure 401 and in direct contact with two opposite side surfaces 530 and 520 of the CTE adjusting component 500. In some embodiments, the underfill material 700 is made of liquid epoxy, deformable gel, silicon rubber, another applicable material, or a combination thereof. In addition, a dispensing process may be performed to form the underfill material 700 by using a dispensing tool, and then the material of the underfill material 700 may be cured to harden.

In general, the coefficient of thermal expansion (CTE) of the underfill material 700 is significantly higher than that of silicon and/or the substrate material of the die stack structure 401. For example, when the semiconductor substrates 20, 44A, 44B are silicon substrates, the silicon substrate may have a CTE of approximately 3.2 ppm/K. In this case, the underfill material 700 may be formed using epoxy resin with a CTE of approximately 10 to 20 ppm/K. This type of CTE mismatch causes each one of the materials to expand a different distance when the semiconductor package is heated during later processing, testing or use. As such, at elevated temperatures, there is a CTE mismatch that causes stresses to form between the different materials and, hence, the different parts of the semiconductor package. If not controlled, these stresses can cause cracked in the underfill material 700, delamination between the various material, especially the delamination of the bonding interface S1 between the first die 201 and the second die 301 of the die stack structure 401. This delamination can damage or even destroy the semiconductor package 10 during the manufacturing process or else during its intended use.

Accordingly, the CTE adjusting component 500 made of composite material for adjusting issues of CTE mismatch of the semiconductor package 10 is provided. In some embodiments, the method of forming the CTE adjusting component 500 may involve laminating a plurality of material layers together, and a CTE of one of the material layers is different from a CTE of another one of the material layers. For example, the CTE adjusting component 500 may include a first material layer adjacent to a first side of the CTE adjusting component 500, and a second material layer adjacent to a second side of the CTE adjusting component 500. An optional third material layer of the CTE adjusting component 500 may be located between the first material layer and the second material layer. The material layers may each include thin sheets of structural material that may be bonded together through lamination or using a suitable adhesive, such as an adhesive film, to form the CTE adjusting component 500. In some embodiments, the material layers may be bonded together using a partially-cured epoxy resin, such as a B-stage material. The B-stage material may include one or more layers (i.e., plies) of a prepreg material that includes a glass fiber or cloth material impregnated with a resin that may be partially-dried via heat and/or UV radiation. In various embodiments, the material layers may be stacked with one or more layers of B-stage prepreg material located between the material layers, respectively, and subjected to a press lamination process and a final cure to form the CTE adjusting component 500. In some embodiments, a layer of copper foil may be provided over the upper and lower surfaces of the stack during the press lamination process to provide the CTE adjusting component 500 including layers of copper material over the first side 530 (see FIG. 10) and the second side 520 (see FIG. 10) of the CTE adjusting component 500. It may be understood that other configurations for the CTE adjusting component 500 are within the contemplated scope of disclosure, including embodiments in which the CTE adjusting component 500 may be formed as a unitary structure including multiple material layers laminated over one another.

In some embodiments, the material layers of the CTE adjusting component 500 may each be composed of a sheet of laminate reinforced resin. The laminate reinforced resin sheet may include a reinforcement material (e.g., glass fiber or cloth) that is impregnated with a resin system, such as an epoxy-based resin system, and is cured under heat and pressure to form a sheet of laminate reinforced resin. Other suitable materials and constructions for the material layers of the CTE adjusting component 500 are within the contemplated scope of disclosure.

In various embodiments, the material layers of the CTE adjusting component 500 may each has different material properties, such as a different coefficient of thermal expansion (CTE) and/or a different modulus of elasticity (i.e., Young's modulus). In various embodiments, the first material layer of the CTE adjusting component 500 may have a CTE that is different from the CTE of the second material layer of the CTE adjusting component 500. Accordingly, the overall CTE of the CTE adjusting component 500 may be easily controlled by simply adjusting the proportion of the material layers with different CTE.

The differences in material properties between the material layers of the CTE adjusting component 500 may help to balance the effects of stress, such as thermally-induced stress, when the die stack structure 401 is assembled in the semiconductor package. The material layer with lower CTE may be in closest proximity to the die stack structure 401 including one or more device dies. Thus, the lower CTE of the first material layer may more closely match the relatively lower CTE of components of the die stack structure 401, including the one or more dies. The relatively higher Young's modulus (e.g., higher than Young's modulus of the underfill material) of the CTE adjusting component 500 may provide a higher resistance to mechanical strain, which may help to maintain the structural integrity of the semiconductor package.

The different material properties of the material layers of the CTE adjusting component 500 may be obtained by varying different process parameters and/or materials. In the case of laminate reinforced resin materials, for example, such variations may include, without limitation, variations in the composition of the reinforcement material, including the type of reinforcement material used (e.g., E-glass, S-Glass, LowDk-glass, silica, quartz, aramid, etc.), variations in the physical characteristics of the reinforcement material (e.g., use of woven or non-woven fiber reinforcement material, weave pattern of woven fiber reinforcement material, diameter, length and/or alignment of fiber reinforcement material, etc.), variations in the composition of the resin system utilized, variations in the curing process, and variations in the relative concentrations of reinforcement material and resin in the laminate reinforced resin product. A number of commercially available products may be suitable for use in various embodiments of the invention. For example, in recent years a number of substrate core materials characterized by low- or extra-low CTE and high Young's modulus have come onto the market and may be suitable for use as one of the material layers of the CTE adjusting component 500. Examples of suitable products for one of the composite material of the CTE adjusting component 500 may include, without limitation, glass fiber mixed with resin, silica mixed with resin, ceramic composites, polymer composites, or the like.

In some embodiments, a CTE of the CTE adjusting component 500 is designed to be substantially lower than a CTE of the underfill material 700 at a temperature being substantially equal to or higher than 200 Celsius. For example, the CTE of the CTE adjusting component 500 is about equal to or lower than about 7 ppm/° C. at the temperature being substantially equal to or higher than about 200 Celsius. In one embodiment, the CTE of the CTE adjusting component 500 is about 3 ppm/C or lower at the temperature being substantially equal to or higher than about 200 Celsius. Accordingly, the amount of the underfill material 700 using in the semiconductor package 10 is reduced by embedding the CTE adjusting component 500 in the underfill material 700, so the thermal stress caused by CTE mismatch between the die stack structure 401 and the underfill material 700 can be reduced. Moreover, the underfill material 700 is in contact with both of the first side surface 530 (e.g., the surface facing the die stack structure 401) and the second side surface 520 (e.g., the surface opposite to the first side surface 530) of the CTE adjusting component 500, so the contact area and bonding strength between the underfill material 700 and the CTE adjusting component 500 is increased. Accordingly, at high temperature such as a temperature that is higher than about 200 Celsius, the underfill material 700 suffers great amount of thermal expansion while the CTE adjusting component 500 with much lower CTE can pull back the expansion of the underfill material 700, so as to further reduce the thermal stress in the semiconductor package 10 at higher temperature (e.g., over 200 Celsius).

In addition, the CTE of the CTE adjusting component 500 is substantially higher than a CTE of the die stack structure 401 at a temperature being substantially equal to or lower than about 100 Celsius. For example, the CTE of the CTE adjusting component 500 is substantially equal to or higher than about 15 ppm/° C. at a temperature being substantially equal to or lower than 100 Celsius. In one embodiment, the CTE of the CTE adjusting component 500 is substantially equal to or higher than about 25 ppm/° C. at room temperature, which ranges from about 20 Celsius to about 30 Celsius. Accordingly, by embedding the CTE adjusting component 500 in the underfill material 700, when the semiconductor package 10 is cooled down (e.g., below 100 Celsius or at room temperature), the underfill material 700 and the die stack structure 401 both suffer great amount of thermal contraction while the CTE adjusting component 500 with higher CTE at room temperature can reduce the amount of thermal contraction of the underfill material 700 and the die stack structure 401, so as to reduce the thermal stress in the semiconductor package 10 at lower temperature (e.g., below 100 Celsius or at room temperature).

The recitation of a particular numerical value or value range herein is understood to include or be a recitation of an approximate numerical value or value range (e.g., within +/−20%, +/−10%, or +/−5%). Similarly, the recitation of equivalence, essential equivalence, or approximate equivalence is understood to encompass actual equality as well as essential or approximate equivalence (e.g., identical to within +/−20%, +/−10%, or +/−5%).

In accordance with some embodiments of the disclosure, some dimensions of the CTE adjusting component 500 may be controlled to further enhance the bonding strength between the CTE adjusting component 500 and the underfill material 700a. For example, a top surface of the CTE adjusting component 500 is designed to be at least higher than the bonding interface S1 between the first die 201 and the second die 301 to effectively prevent the bonding interface S1 from delamination. In one embodiment, a height H2 of the CTE adjusting component 500 is substantially 60% to 90% of a height H1 of the die stack structure 401. In some embodiments, the gap G1 between the die stack structure 401 and the CTE adjusting component 500 ranges from about 50 μm to about 200 μm. The width (thickness) W1 of the CTE adjusting component 500 is substantially equal to or greater than about 100 μm. However, the disclosure is not limited thereto. In some embodiments, the underfill material 700 may fully encapsulate the side surfaces of the die stack structure 401.

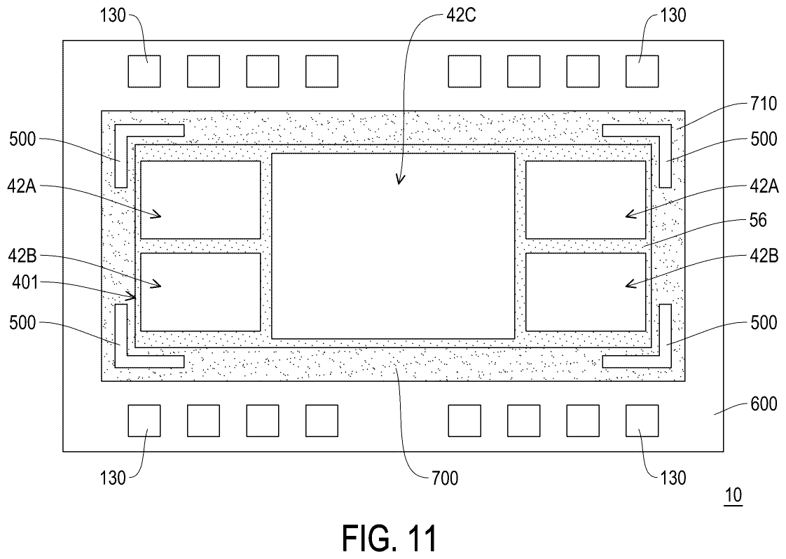

FIG. 11 illustrates a perspective top view of the semiconductor package according to some embodiments of the present disclosure. It is noted that the configuration of the components (e.g., the device dies 42A, 42B, 42C, passive components 130, etc.) on the substrate 600 is merely for illustration, the actual layout may be similar to, the same as or different from the configuration shown in the figures. Also, the number of device dies 42A, 42B, 42C in the die stack structure 401, and the number of the passive components 130 are not limited thereto. In some embodiments, the passive components 130 are disposed around and separated from the die stack structure 401.

In accordance with some embodiments, the die stack structure 401 and a plurality of passive components 130 are bonded to the substrate 600 as shown in FIG. 11. In the present embodiment, the CTE adjusting component 500 at least partially surrounds a plurality of corners of the die stack structure 401. To be more specific, the CTE adjusting component 500 includes four L-shaped portions, and each of the L-shaped portions is disposed around each of the corners of the die stack structure 401 in the top view of FIG. 11, in accordance with some embodiments. In accordance with some embodiments, the underfill material 700 has an extending portion 710 that extending beyond the surrounding region of the CTE adjusting component 500 and in contact with two opposite side surfaces of the CTE adjusting component 500 as shown in FIG. 11. It is noted that the contour of the underfill material 700 from the top view may not be as neat and straight as it is shown in FIG. 11.

In general, most of the delamination between the bonding interface of the dies 201, 301 and cracks in the underfill material 700 occur in the locations around the corners of the die stack structure 401. Accordingly, disposing the L-shaped portions of the CTE adjusting component 500 around the corners of the die stack structure 401 is an economical way to mitigate or eliminate the problem with lower process cost. In addition, since the CTE adjusting component (i.e., dam structure) 500 is disposed between the die stack structure 401 and the passive components 130, the CTE adjusting component 500 can somewhat be functioned as a dam structure to stop the underfill material 700 from overflowing too far away from the confinement of the CTE adjusting component 500, so that the underfill material 700 may be prevented from contacting the passive components 130, and damages to the passive components 130 can be prevented.

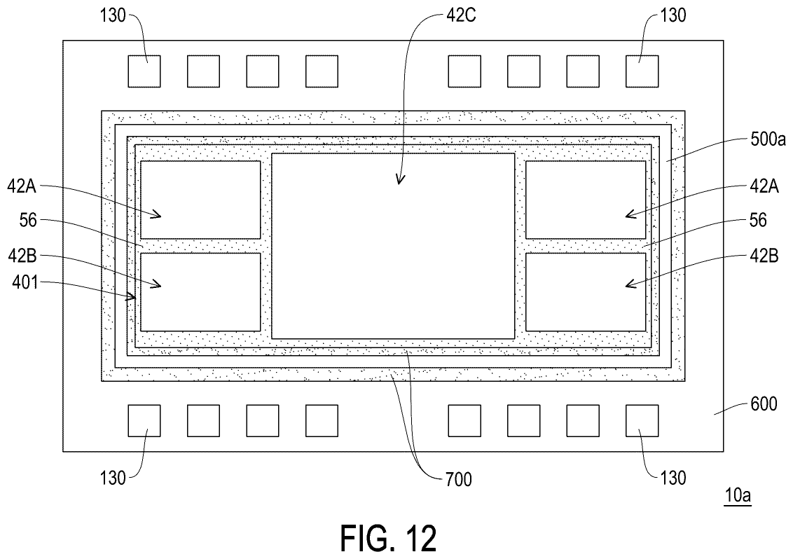

FIG. 12 to FIG. 14 illustrate perspective top views of semiconductor packages according to different embodiments of the present disclosure. It is noted that the semiconductor packages shown in FIG. 12 to FIG. 14 contain many features same as or similar to the semiconductor package disclosed earlier in the previous embodiments. For purpose of clarity and simplicity, detail description of same or similar features may be omitted, and the same or similar reference numbers denote the same or like components.

Referring to FIG. 12, in the present embodiment, similar to the structure of FIG. 11, a CTE adjusting component 500a and the underfill material 700 are formed in the semiconductor package 10a as shown in FIG. 12. The difference between the CTE adjusting component 500a of FIG. 111 and the CTE adjusting component 500a of FIG. 12 is that the CTE adjusting component 500a is formed surrounding the edges of the die stack structure 401. In the embodiment, the CTE adjusting component 500a formed a closed rectangular dam structure that fully surrounds the die stack structure 401.

In accordance with some embodiments, the underfill material 700 has an extending portion that extending beyond the enclosed region of the CTE adjusting component 500a and in contact with two opposite side surfaces of the CTE adjusting component 500a as shown in FIG. 12. Therefore, the delamination and cracking issues in the semiconductor package 10a may be mitigated or eliminated. In addition, since the CTE adjusting component 500a is disposed between the die stack structure 401 and the passive components 130, the CTE adjusting component 500a can somewhat be functioned as a dam structure to stop the underfill material 700 from overflowing too far away from the confinement of the CTE adjusting component 500a, so that the underfill material 700 may be prevented from contacting the passive components 130, and damages to the passive components 130 can be prevented.

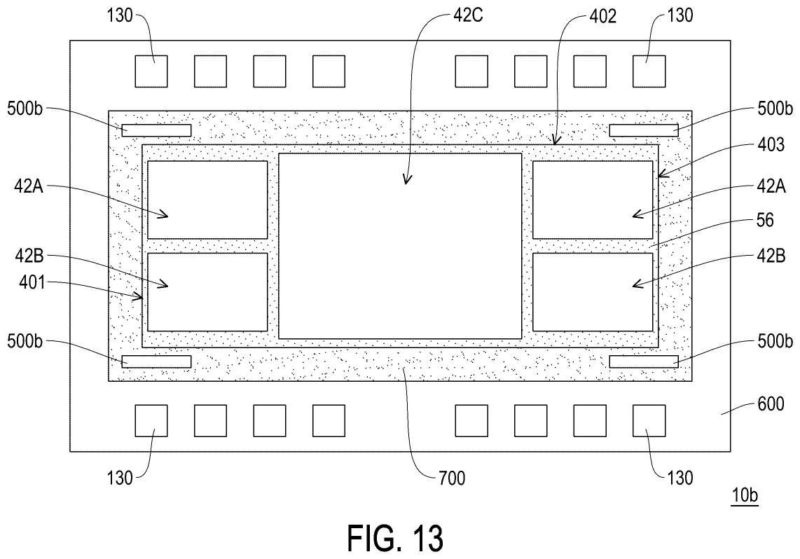

Referring to FIG. 13, in the present embodiment, the CTE adjusting component 500b partially surrounds the corners of the die stack structure 401. To be more specific, the die stack structure 401 includes two long sides 402 and two short sides 403, and one of the long sides 402 and the adjacent one of the short sides 403 forms a corner of the die stack structure 401. The CTE adjusting component 500b includes four wall portions, and each of the wall portions disposed by the long side 402 of the corner in the top view of FIG. 13, in accordance with some embodiments. In accordance with some embodiments, the underfill material 700 has an extending portion 710 that extending beyond the surrounding region of the CTE adjusting component 500b and in contact with two opposite side surfaces of the CTE adjusting component 500b as shown in FIG. 13.

In general, most of the delamination between the bonding interface of the dies 201, 301 and cracks in the underfill material 700 occur in the locations around the corners of the die stack structure 401. Accordingly, disposing the CTE adjusting components 500b around the corners of the die stack structure 401 is an economical way to mitigate or eliminate the problem with lower process cost. Therefore, the delamination and cracking issues in the semiconductor package 10b may be mitigated or eliminated. In addition, since the CTE adjusting component (i.e., dam structure) 500b is disposed between the die stack structure 401 and the passive components 130, the CTE adjusting component 500b can somewhat be functioned as a dam structure to stop the underfill material 700 from overflowing too far away from the confinement of the CTE adjusting component 500b, so that the underfill material 700 may be prevented from contacting the passive components 130, and damages to the passive components 130 can be prevented.

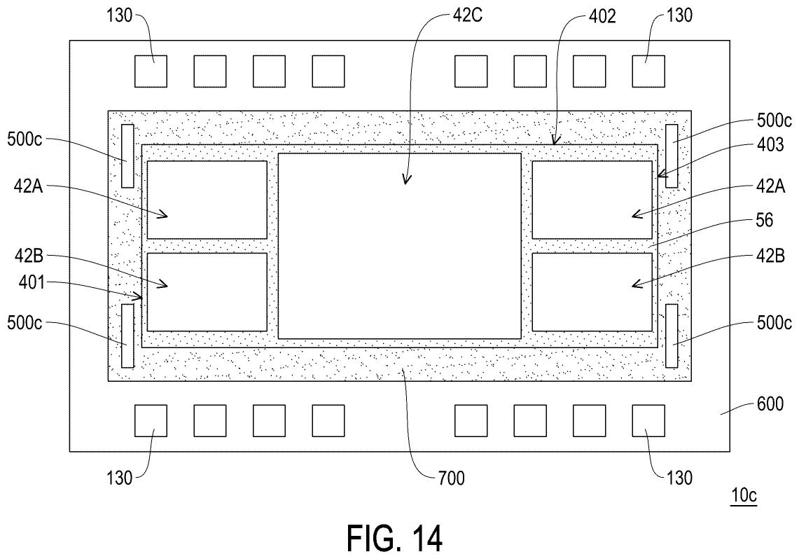

On the other hand, referring to FIG. 14, in the present embodiment, the CTE adjusting component 500b partially surrounds the corners of the die stack structure 401. To be more specific, the die stack structure 401 includes two long sides 402 and two short sides 403, and one of the long sides 402 and the adjacent one of the short sides 403 forms a corner of the die stack structure 401. The CTE adjusting component 500c includes four wall portions, and each of the wall portions disposed by the short side 403 of the corner in the top view of FIG. 14. In accordance with some embodiments, the underfill material 700 has an extending portion that extending beyond the enclosed region of the CTE adjusting component 500c and in contact with two opposite side surfaces of the CTE adjusting component 500c as shown in FIG. 14.

In general, most of the delamination between the bonding interface of the dies 201, 301 and cracks in the underfill material 700 occur in the locations around the corners of the die stack structure 401. Accordingly, disposing the CTE adjusting components 500c around the corners of the die stack structure 401 is an economical way to mitigate or eliminate the problem with lower process cost. Therefore, the delamination and cracking issues in the semiconductor package 10c may be mitigated or eliminated.

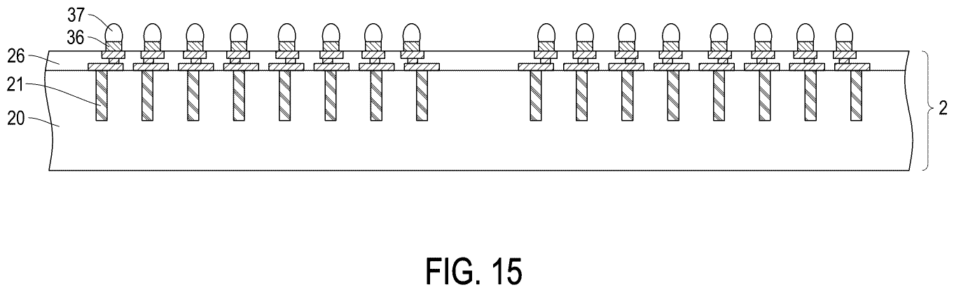

FIG. 15 to FIG. 23 illustrate cross sectional views of intermediate stages in the manufacturing of a semiconductor package according to some embodiments of the present disclosure. The CTE adjusting components 500, 500a, 500b, 500c not only can be applied in the semiconductor package such as a System on Integrate Chip (SoIC) package as it is shown above, but also can be applied to other suitable packages that suffers thermal stress caused by CTS mismatch of the underfill material 700 and the semiconductor device 401. FIG. 15 to FIG. 23 illustrate one of the possible packages such as a Chip on Wafer on Substrate (CoWoS®) that can adopt the configuration of the CTE adjusting components 500, 500a, 500b, 500c.

FIG. 15 illustrates the formation of a first side of a wafer 2. As illustrated in FIG. 15, the wafer 2 may be an interposer or another die. The wafer 2 includes a substrate 20, which is in a wafer form. The substrate 20 may include a bulk semiconductor substrate, SOI substrate, multi-layered semiconductor substrate, or the like. The semiconductor material of the substrate 20 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 20 may be doped or undoped. Devices, such as transistors, capacitors, resistors, diodes, and the like, may be formed in and/or on an upper surface, which may also be referred to as an active surface, of the substrate 20. In embodiments where the wafer 2 is an interposer wafer, the wafer 2 will generally not include active devices therein, although the interposer may include passive devices formed in and/or on the substrate 20 and/or in redistribution structure 26.

A plurality of through vias 21 are formed to extend from the upper surface of substrate 20 into substrate 20. The through vias 21 are also sometimes referred to as through-substrate vias or through-silicon vias when substrate 20 is a silicon substrate. The through vias 21 may be formed by forming recesses in the substrate 20 by, for example, etching, milling, laser techniques, a combination thereof, and/or the like. A thin dielectric material may be formed in the recesses, such as by using an oxidation technique. A thin barrier layer may be conformally deposited over the front side of the substrate 20 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 20 by, for example, CMP. Thus, the through vias 21 may comprise a conductive material and a thin barrier layer between the conductive material and the substrate 20.

Then, a redistribution structure 26 is formed over the surface of the substrate 20, and is used to electrically connect the integrated circuit devices, if any, and/or through vias 21 together and/or to external devices. The redistribution structure 26 may include one or more dielectric layer(s) and respective metallization pattern(s) in the dielectric layer(s). The metallization patterns may comprise vias and/or traces to interconnect any devices and/or through vias 21 together and/or to an external device. The metallization patterns are sometimes referred to as Redistribution Lines (RDL). The dielectric layers may comprise silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. A metallization pattern may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVD, or the like. Any excessive diffusion barrier layer and/or conductive material on the dielectric layer may be removed, such as by using a CMP.

Then, a plurality of electrical connectors 36/37 are formed at the top surface of the redistribution structure 26 on conductive pads. In some embodiments, the conductive pads include under bump metallurgies (UBMs). In the illustrated embodiment, the pads are formed in openings of the dielectric layers of the redistribution structure 26. In another embodiment, the pads (UBMs) can extend through an opening of a dielectric layer of the redistribution structure 26 and also extend across the top surface of the redistribution structure 26. As an example to form the pads, a seed layer (not shown) is formed at least in the opening in the dielectric layer of the redistribution structure 26. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photo resist is then formed and patterned on the seed layer. The photo resist may be formed by spin coating or the like and may be exposed to light for patterning. The pattern of the photo resist corresponds to the pads. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may comprise a metal, like copper, titanium, tungsten, aluminum, or the like. Then, the photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form the pads. In the embodiment, where the pads are formed differently, more photo resist and patterning steps may be utilized.

In some embodiments, the electrical connectors 36/37 include a metal pillar 36 with a metal cap layer 37, which may be a solder cap 37, over the metal pillar 36. The electrical connectors 36/37 including the pillar 36 and the cap layer 37 are sometimes referred to as micro bumps 36/37. In some embodiments, the metal pillars 36 include a conductive material such as copper, aluminum, gold, nickel, palladium, the like, or a combination thereof and may be formed by sputtering, printing, electro plating, electroless plating, CVD, or the like. The metal pillars 36 may be solder free and have substantially vertical sidewalls. In some embodiments, a metal cap layer 37 is formed on the top of the metal pillar 36. The metal cap layer 37 may include nickel, tin, tin-lead, gold, copper, silver, palladium, indium, nickel-palladium-gold, nickel-gold, the like, or a combination thereof and may be formed by a plating process.

In another embodiment, the electrical connectors 36/37 do not include the metal pillars and are solder balls and/or bumps, such as controlled collapse chip connection (C4), electroless nickel immersion Gold (ENIG), electroless nickel electroless palladium immersion gold technique (ENEPIG) formed bumps, or the like. In this embodiment, the bump electrical connectors 36/37 may include a conductive material such as solder, copper, aluminum, gold, nickel, silver, palladium, tin, the like, or a combination thereof. In this embodiment, the electrical connectors 36/37 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes.

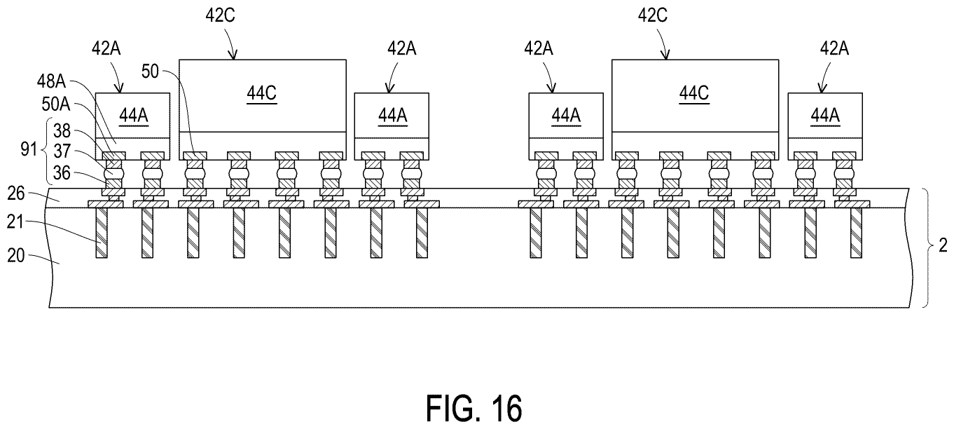

In FIG. 16, the device dies 42A, and the device die 42C are attached to the first side of the wafer 2, for example, through flip-chip bonding by way of the electrical connectors 36/37 and the metal pillars 38 on the dies to form conductive joints 91. In some embodiment, the device dies 42B as shown in FIG. 11 may also be attached to the wafer 2, but cannot be seen from this cross section view). The metal pillars 38 may be similar to the metal pillars 36 and the description is not repeated herein. The device dies 42A, 42C may be placed on the electrical connectors 36/37 using, for example, a pick-and-place tool. In some embodiments, the metal cap layers 37 are formed on the metal pillars 36 (as shown in FIG. 3), the metal pillars 38 of the device dies 42A and 44C, or both.

The device dies 42A may be formed through similar processing as described above in reference to the device dies 42C. In some embodiments, the device dies 42A include one or more memory dies, such as a stack of memory dies (e.g., DRAM dies, SRAM dies, High-Bandwidth Memory (HBM) dies, Hybrid Memory Cubes (HMC) dies, or the like). In the stack of memory dies embodiments, a device die 42A can include both memory dies and a memory controller, such as, for example, a stack of four or eight memory dies with a memory controller. Also, in some embodiments, the device dies 42A may be different sizes (e.g., different heights and/or surface areas), and in other embodiments, the dies 88 may be the same size (e.g., same heights and/or surface areas).

The device dies 42A/42C include a main body 44A/44C, an interconnect structure 48A/48C, and die connectors 50A/50C. The main body 44A/44C of the device dies 42A/42C may include any number of dies, substrates, transistors, active devices, passive devices, or the like. In an embodiment, the main body 44A/44C may include a bulk semiconductor substrate, semiconductor-on-insulator (SOI) substrate, multi-layered semiconductor substrate, or the like. The semiconductor material of the main body 44A/44C may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The main body 44A/44C may be doped or undoped. Devices, such as transistors, capacitors, resistors, diodes, and the like, may be formed in and/or on an active surface.

An interconnect structure 48A/48C including one or more dielectric layer(s) and respective metallization pattern(s) is formed on the active surface. The metallization pattern(s) in the dielectric layer(s) may route electrical signals between the devices, such as by using vias and/or traces, and may also contain various electrical devices, such as capacitors, resistors, inductors, or the like. The various devices and metallization patterns may be interconnected to perform one or more functions. The functions may include memory structures, processing structures, sensors, amplifiers, power distribution, input/output circuitry, or the like. Additionally, die connectors 50A/50C, such as conductive pillars (for example, comprising a metal such as copper), are formed in and/or on the interconnect structure 48A/48C to provide an external electrical connection to the circuitry and devices. In some embodiments, the die connectors 50A/50C protrude from the interconnect structure 84 to form pillar structure to be utilized when bonding the device dies 42A/42C to other structures. One of ordinary skill in the art will appreciate that the above examples are provided for illustrative purposes. Other circuitry may be used as appropriate for a given application.

More particularly, an IMD layer may be formed in the interconnect structure 48A/48C. The IMD layer may be formed, for example, of a low-K dielectric material, such as PSG, BPSG, FSG, SiOxCy, Spin-On-Glass, Spin-On-Polymers, silicon carbon material, compounds thereof, composites thereof, combinations thereof, or the like, by any suitable method known in the art, such as spinning, CVD, PECVD, HDP-CVD, or the like. A metallization pattern may be formed in the IMD layer, for example, by using photolithography techniques to deposit and pattern a photoresist material on the IMD layer to expose portions of the IMD layer that are to become the metallization pattern. An etch process, such as an anisotropic dry etch process, may be used to create recesses and/or openings in the IMD layer corresponding to the exposed portions of the IMD layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by ALD, or the like. The conductive material of the metallization patterns may comprise copper, aluminum, tungsten, silver, and combinations thereof, or the like, deposited by CVD, PVD, or the like. Any excessive diffusion barrier layer and/or conductive material on the IMD layer may be removed, such as by using a CMP.

In the embodiments wherein the die connectors 50A/50C protrude from the interconnect structures 48A/48C, respectively, the metal pillars 38 may be excluded from the device dies 42A/42C as the protruding die connectors 50A/50C may be used as the pillars for the metal cap layers 37.

The conductive joints 91 electrically couple the circuits in the device dies 42A and the device dies 42C through the interconnect structures 48A and 48C and the die connectors 50A and 50C, respectively, to the redistribution structure 26 and through vias 21 in the wafer 2.

In some embodiments, before bonding the electrical connectors 36/37, the electrical connectors 36/37 are coated with a flux (not shown), such as a no-clean flux. The electrical connectors 36/37 may be dipped in the flux or the flux may be jetted onto the electrical connectors 36/37. In another embodiment, the flux may be applied to the electrical connectors 38/37. In some embodiments, the electrical connectors 36/37 and/38/37 may have an epoxy flux (not shown) formed thereon before they are reflowed with at least some of the epoxy portion of the epoxy flux remaining after the device dies 42A and the device dies 42C are attached to the wafer 2. This remaining epoxy portion may act as an underfill to reduce stress and protect the joints resulting from the reflowing the electrical connectors 36/37/38.

In an embodiment, the device dies 42A and 42C are bonded to the interposer wafer 2 by a reflow process. During this reflow process, the electrical connectors 36/37/38 are in contact with the device dies 42A and 42C, respectively, and the pads of the redistribution structure 26 to physically and electrically couple the device dies 42A and 42C to the wafer 2. After the bonding process, an IMC (not shown) may form at the interface of the metal pillars 36 and 38 and the metal cap layers 37.

In some embodiments, device die 42C may be a system-on-a-chip (SoC) or a graphics processing unit (GPU) and the second dies are memory dies that may utilized by the dies 68. In an embodiment, the device dies 42A are stacked memory dies. For example, the stacked memory dies 42A may include low-power (LP) double data rate (DDR) memory modules, such as LPDDR1, LPDDR2, LPDDR3, LPDDR4, or the like memory modules.

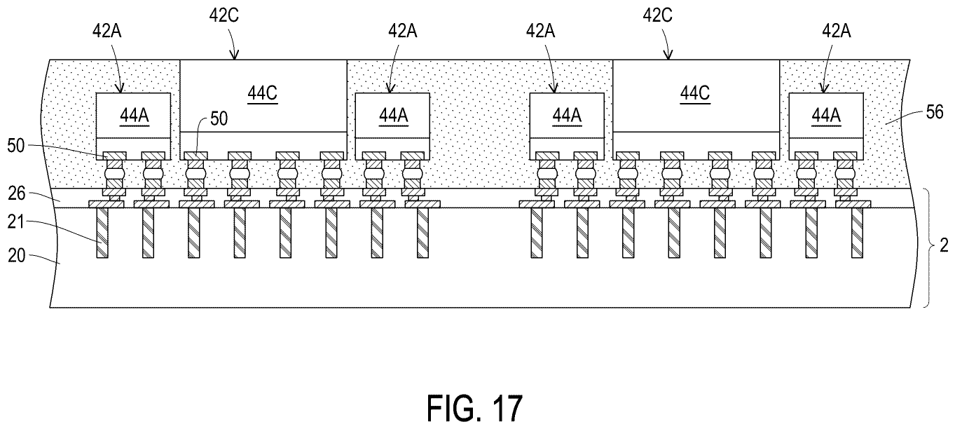

In FIG. 17, an encapsulating material 56 is formed on the various components. The encapsulating material 56 may be a molding compound, epoxy, or the like, and may be applied by compression molding, transfer molding, or the like. A curing step is performed to cure the encapsulating material 56, wherein the curing may be a thermal curing, a Ultra-Violet (UV) curing, or the like. In some embodiments, the device dies 42A, 42C are buried in the encapsulating material 56, and after the curing of the encapsulating material 56, a planarization step, such as a grinding, may be performed to remove excess portions of the encapsulating material 56, which excess portions are over top surfaces of the device dies 42A, 42C. Accordingly, top surfaces of the device dies 42A, 42C are exposed, and are level with a top surface of the encapsulating material 56.

In some embodiments, an underfill material may be optionally dispensed into the gaps between the device dies 42A, 42C and the redistribution structure 26, and surrounding the conductive joints 91 before the encapsulating material 56 is formed. The underfill material may extend up along sidewall of the device dies 42A, 42C. The underfill material may be any acceptable material, such as a polymer, epoxy, molding underfill, or the like. The underfill material may be formed by a capillary flow process after the device dies 42A, 42C are attached, or may be formed by a suitable deposition method before the device dies 42A, 42C are attached.

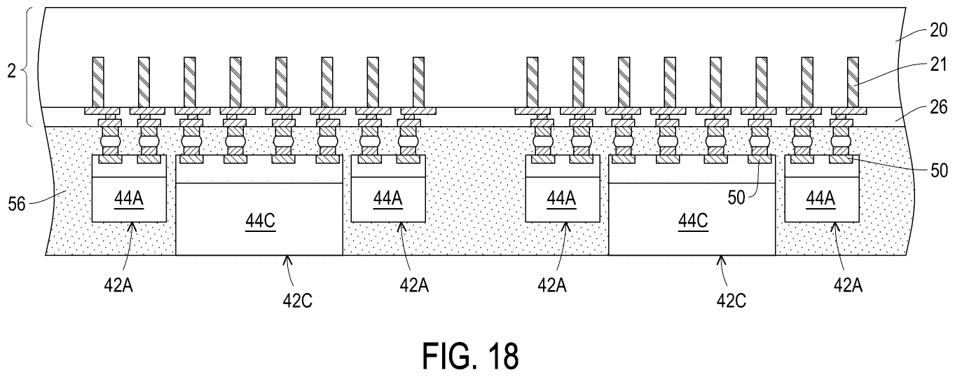

FIG. 18 through FIG. 20 illustrate the formation of the second side of the wafer 2. In FIG. 18, the structure of FIG. 17 is flipped over to prepare for the formation of the second side of the wafer 2. Although not shown, the structure may be placed on a carrier or support structure for the process of FIG. 18 through FIG. 20.

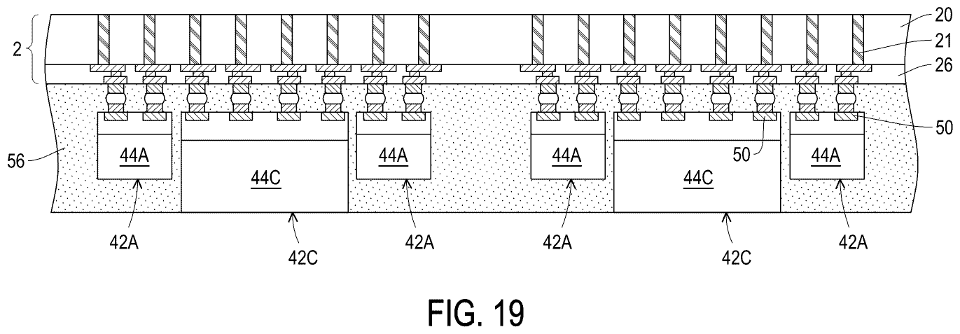

In FIG. 19, a thinning process is performed on the second side of the substrate 20 to thin the substrate 20 until the through vias 21 are exposed. The thinning process may include an etching process, a grinding process, the like, or a combination thereof.

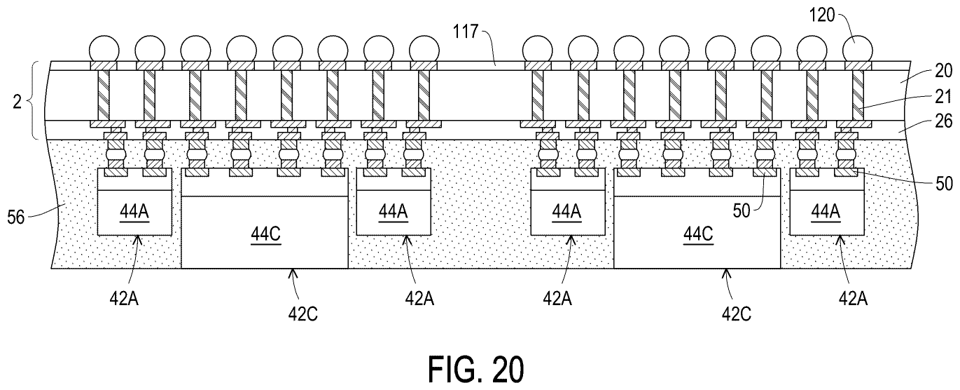

In FIG. 20, a redistribution structure 117 is formed on the second side of the substrate 20, and is used to electrically connect the through vias 21 together and/or to external devices. The redistribution structure 117 includes one or more dielectric layers and metallization patterns in the one or more dielectric layers. The metallization patterns may comprise vias and/or traces to interconnect through vias 21 together and/or to an external device. The metallization patterns are sometimes referred to as Redistribution Lines (RDLs). The dielectric layers may comprise silicon oxide, silicon nitride, silicon carbide, silicon oxynitride, low-K dielectric material, such as PSG, BPSG, FSG, SiOxCy, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. The metallization patterns may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVC, or the like. Any excessive diffusion barrier layer and/or conductive material on the dielectric layer may be removed, such as by using a CMP.

Then, a plurality of conductive bumps 120 are also formed the metallization patterns of the redistribution structure 117 and are electrically coupled to the through vias 21. The conductive bumps 120 are formed at the top surface of the redistribution structure 117. In some embodiments, the redistribution structure 117 include UBMs. In the illustrated embodiment, the pads are formed in openings of the dielectric layer of the redistribution structure 117. In another embodiment, the pads (UBMs) can extend through an opening of a dielectric layer of the redistribution structure 117 and also extend across the top surface of the redistribution structure 117.

In some embodiments, the conductive bumps 120 are solder balls and/or bumps, such as ball grid array (BGA) balls, C4 micro bumps, ENIG formed bumps, ENEPIG formed bumps, or the like. The conductive bumps 120 may include a conductive material such as solder, copper, aluminum, gold, nickel, silver, palladium, tin, the like, or a combination thereof. In some embodiments, the conductive bumps 120 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive bumps 120 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar connectors 120. The metal cap layer may include nickel, tin, tin-lead, gold, silver, palladium, indium, nickel-palladium-gold, nickel-gold, the like, or a combination thereof and may be formed by a plating process.

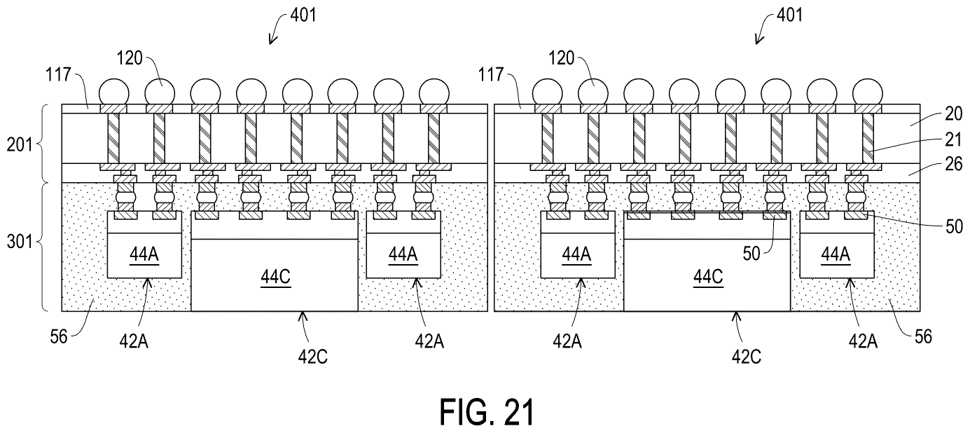

Then, referring to FIG. 21, a singulation (die-saw) process is performed on the resulting structure shown in FIG. 20 to separate the resulting structure into a plurality of semiconductor devices 401. In some embodiments, the semiconductor device 401 can be seen as a die stack structure, which includes a first die 201, and a second die 301 stacked over and bonded to the first die 201. The singulation process may include sawing, dicing, or the like. To be more specific, the singulation process is performed on the encapsulating material 56 and the wafer 2 to separate the composite wafer into a plurality of die stack structures 401. After the singulation process, the first die 201 is singulated from the interposer wafer 2, and the second die 301 is singulated from the reconstructed wafer 3 and bonded to the first die 201 through flip chip bonding.

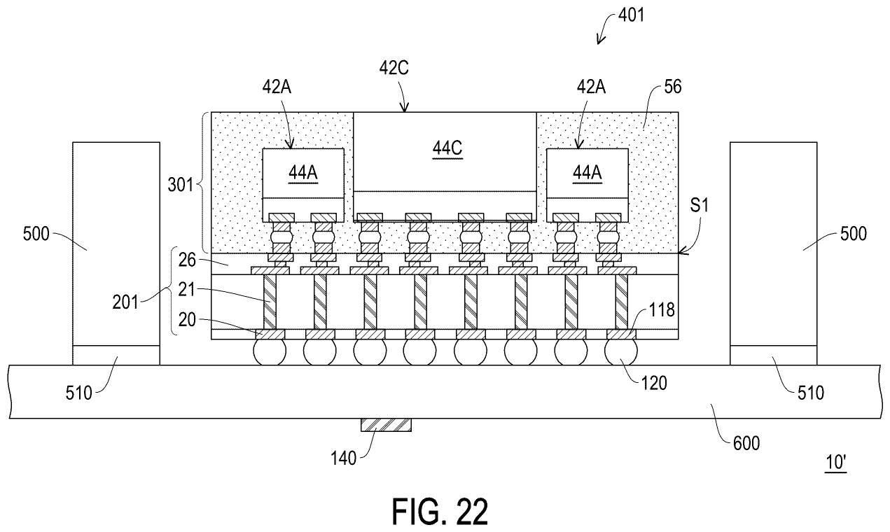

In FIG. 22, the semiconductor device 401 is bonded onto the substrate 600. The conductive bumps 120 are aligned to, and are put against, the bond pads of the substrate 600. The conductive bumps 120 may be reflowed to create a bond between the substrate 600 and the semiconductor device 401. The substrate 600 may include a package substrate, such as a build-up substrate including a core therein, a laminate substrate including a plurality of laminated dielectric films, a PCB, or the like. The substrate 600 may include electrical connectors (not shown), such as solder balls, opposite the component package to allow the substrate 600 to be mounted to another device.

Then, a dam structure 500 is attached onto the substrate 600 in accordance with some embodiments. More specifically, the dam structure 500 at least partially surrounds the semiconductor device 401 in accordance with some embodiments. The dam structure 500 may be attached to the substrate through the adhesive 510 such as a die attach film (DAF), or the like. In some embodiments, the dam structure 500 can be seen as a coefficient of thermal expansion (CTE) adjusting component, which is made of composite material for adjusting issues of CTE mismatch of the semiconductor package. The characteristics of the CTE adjusting component 500 have been described above and are not repeated herein.

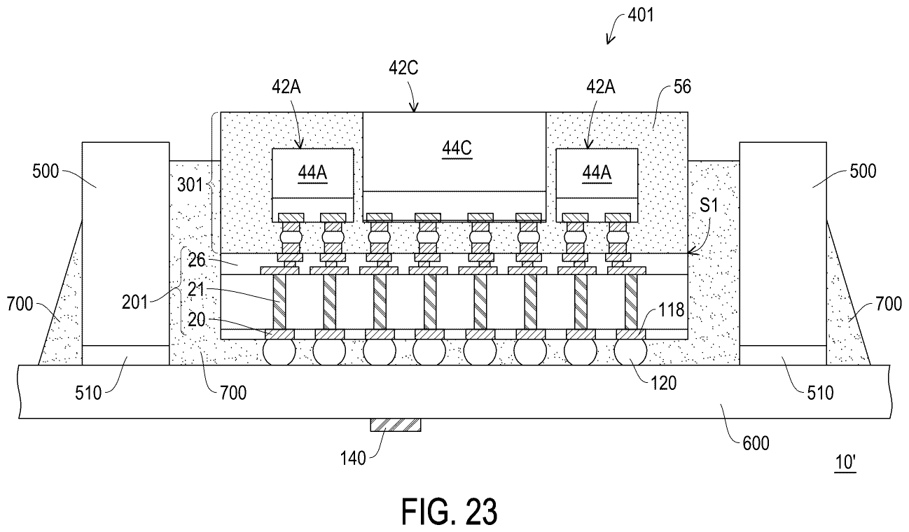

Referring to FIG. 23, then, an underfill material 700 is provided over the substrate 600. The underfill material 700 is filled in the space between the substrate 600 and the semiconductor device 401, and the underfill material 700 encapsulates side surfaces of the semiconductor device 401 and in direct contact with two opposite side surfaces of the CTE adjusting component 500. In some embodiments, the underfill material 700 is made of liquid epoxy, deformable gel, silicon rubber, another applicable material, or a combination thereof. In addition, a dispensing process may be performed to form the underfill material 700 by using a dispensing tool, and then the material of the underfill material 700 may be cured to harden. Therefore, the delamination between the bonding interface of the dies 201, 301 and cracks in the underfill material 700 can be effectively mitigated or eliminated through the help of the CTE adjusting component 500.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a substrate, a semiconductor device bonded over the substrate, a coefficient of thermal expansion (CTE) adjusting component bonded over the substrate and at least partially surrounding the semiconductor device, and an underfill material disposed between the substrate and the semiconductor device and encapsulating side surfaces of the semiconductor device and the CTE adjusting component, wherein a CTE of the CTE adjusting component is substantially lower than a CTE of the underfill material at a temperature being substantially equal to or higher than 200 Celsius. In one embodiment, the CTE of the CTE adjusting component is substantially equal to or lower than 7 ppm/° C. at the temperature being substantially equal to or higher than 200 Celsius. In one embodiment, the CTE of the CTE adjusting component is substantially higher than a CTE of the semiconductor device at a temperature being substantially equal to or lower than 100 Celsius. In one embodiment, the CTE of the CTE adjusting component is substantially equal to or higher than 15 ppm/° C. at a temperature being substantially equal to or lower than 100 Celsius. In one embodiment, the CTE adjusting component at least partially surrounds a plurality of corners of the semiconductor device. In one embodiment, the CTE adjusting component comprises a first side surface facing the semiconductor device and a second side surface opposite to the first side surface, and the underfill material is in contact with the first side surface and the second side surface. In one embodiment, the CTE adjusting component comprises a composite material composed of a first material layer having a first CTE and a second material layer having a second CTE different from the first CTE and laminated with the first material layer. In one embodiment, the semiconductor device comprises a first die and a second die stacked over and bonded to the first die. In one embodiment, a top surface of the CTE adjusting component is substantially higher than a bonding interface between the first die and the second die. In one embodiment, a height of the CTE adjusting component is substantially 60% to 90% of a height of the semiconductor device.

In accordance with some embodiments of the disclosure, a semiconductor package includes a substrate, a die stack structure bonded over the substrate, a dam structure bonded over the substrate and at least partially surrounding a plurality of corners of the die stack structure, and an underfill material filled between the substrate and the semiconductor device, encapsulating side surfaces of the die stack structure and two opposite side surfaces of the dam structure. In one embodiment, a CTE of the dam structure is substantially lower than a CTE of the underfill material at a temperature being substantially equal to or higher than 200 Celsius. In one embodiment, the CTE of the dam structure is substantially higher than a CTE of the semiconductor device at a temperature being substantially equal to or lower than 100 Celsius. In one embodiment, the CTE of the dam structure is substantially equal to or lower than 7 ppm/° C. at the temperature being substantially equal to or higher than 200 Celsius, and substantially equal to or higher than 15 ppm/° C. at a temperature being substantially equal to or lower than 100 Celsius. In one embodiment, the die stack structure comprises a first die bonded to the substrate through a plurality of conductive bumps and a second die stacked over and bonded to the first die through fusion bonding and direct metal bonding. In one embodiment, a top surface of the dam structure is substantially higher than a bonding interface between the first die and the second die.

In accordance with some embodiments of the disclosure, a method of manufacturing a semiconductor package includes: providing a die stack structure over a substrate; attaching a dam structure onto the substrate, wherein the dam structure at least partially surrounding a plurality of corners of the die stack structure; and providing an underfill material over the substrate, wherein the underfill material filled between the substrate and the die stack structure, encapsulating side surfaces of the die stack structure and two opposite side surfaces of the dam structure. In one embodiment, providing the die stack structure over the substrate further comprising: bonding a device die to a wafer; forming an encapsulating material over the wafer, wherein the encapsulating material at least laterally encapsulates the device die; performing a singulation process over the encapsulating material and the wafer to form the die stack structure; and bonding the die stack structure to the substrate. In one embodiment, the method of bonding the device die to the wafer comprises fusion bonding and direct metal bonding. In one embodiment, the method of forming the dam structure comprises laminating a first material layer over a second material layer, and a CTE of the first material layer is different from a CTE of the second material layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a semiconductor device bonded over the substrate;
a coefficient of thermal expansion (CTE) adjusting component bonded over the substrate and at least partially surrounding the semiconductor device; and
an underfill material disposed between the substrate and the semiconductor device and encapsulating side surfaces of the semiconductor device and the CTE adjusting component, wherein a CTE of the CTE adjusting component is substantially lower than a CTE of the underfill material at a temperature being substantially equal to or higher than 200 Celsius.

2. The semiconductor package as claimed in claim 1, wherein the CTE of the CTE adjusting component is substantially equal to or lower than 7 ppm/° C. at the temperature being substantially equal to or higher than 200 Celsius.

3. The semiconductor package as claimed in claim 1, wherein the CTE of the CTE adjusting component is substantially higher than a CTE of the semiconductor device at a temperature being substantially equal to or lower than 100 Celsius.

4. The semiconductor package as claimed in claim 1, wherein the CTE of the CTE adjusting component is substantially equal to or higher than 15 ppm/° C. at a temperature being substantially equal to or lower than 100 Celsius.

5. The semiconductor package as claimed in claim 1, wherein the CTE adjusting component at least partially surrounds a plurality of corners of the semiconductor device.

6. The semiconductor package as claimed in claim 1, wherein the CTE adjusting component comprises a first side surface facing the semiconductor device and a second side surface opposite to the first side surface, and the underfill material is in contact with the first side surface and the second side surface.

7. The semiconductor package as claimed in claim 1, wherein the CTE adjusting component comprises a first material layer having a first CTE and a second material layer having a second CTE different from the first CTE and laminated with the first material layer.

8. The semiconductor package as claimed in claim 1, wherein the semiconductor device comprises a first die and a second die stacked over and bonded to the first die.

9. The semiconductor package as claimed in claim 8, wherein a top surface of the CTE adjusting component is substantially higher than a bonding interface between the first die and the second die.

10. The semiconductor package as claimed in claim 1, wherein a height of the CTE adjusting component is substantially 60% to 90% of a height of the semiconductor device.

11. A semiconductor package, comprising:
a substrate;
a die stack structure bonded over the substrate;
a dam structure bonded over the substrate and at least partially surrounding a plurality of corners of the die stack structure; and
an underfill material filled between the substrate and the semiconductor device, wherein the underfill material encapsulates side surfaces of the die stack structure, a first side surface of the dam structure facing the die stack structure and a second side surface of the dam structure opposite to the first side surface.

12. The semiconductor package as claimed in claim 11, wherein a CTE of the dam structure is substantially lower than a CTE of the underfill material at a temperature being substantially equal to or higher than 200 Celsius.

13. The semiconductor package as claimed in claim 11, wherein the CTE of the dam structure is substantially higher than a CTE of the semiconductor device at a temperature being substantially equal to or lower than 100 Celsius.

14. The semiconductor package as claimed in claim 11, wherein the CTE of the dam structure is substantially equal to or lower than 7 ppm/° C. at the temperature being substantially equal to or higher than 200 Celsius, and substantially equal to or higher than 15 ppm/° C. at a temperature being substantially equal to or lower than 100 Celsius.

15. The semiconductor package as claimed in claim 11, wherein the die stack structure comprises a first die bonded to the substrate through a plurality of conductive bumps and a second die stacked over and bonded to the first die through fusion bonding and direct metal bonding.

16. The semiconductor package as claimed in claim 15, wherein a top surface of the dam structure is substantially higher than a bonding interface between the first die and the second die.

17. A method of manufacturing a semiconductor package, comprising:
providing a die stack structure over a substrate;
attaching a dam structure onto the substrate, wherein the dam structure at least partially surrounding a plurality of corners of the die stack structure; and
providing an underfill material over the substrate, wherein the underfill material filled between the substrate and the die stack structure, encapsulating side surfaces of the die stack structure and two opposite side surfaces of the dam structure.

18. The method as claimed in claim 17, wherein providing the die stack structure over the substrate further comprising:
bonding a device die to a wafer;
forming an encapsulating material over the wafer, wherein the encapsulating material at least laterally encapsulates the device die;
performing a singulation process over the encapsulating material and the wafer to form the die stack structure; and
bonding the die stack structure to the substrate.

19. The method as claimed in claim 18, wherein the method of bonding the device die to the wafer comprises fusion bonding and direct metal bonding.

20. The method as claimed in claim 17, wherein the method of forming the dam structure comprises laminating a first material layer over a second material layer, and a CTE of the first material layer is different from a CTE of the second material layer.
